(19) United States
(12) Patent Application Publication
(10) Pub. No.: US 2025/0126805 A1
(43) Pub. Date: Apr. 17, 2025

(54) SEMICONDUCTOR DEVICE AND METHOD FOR FABRICATING THE SAME

(71) Applicant: SK hynix Inc., Icheon-si (KR)

(72) Inventor: Tae Jung HA, Icheon-si (KR)

(21) Appl. No.: 18/767,890

(22) Filed: Jul. 9, 2024

(30) Foreign Application Priority Data
Oct. 11, 2023 (KR) 10-2023-0135130

(51) Int. Cl. H10B 61/00; H10N 50/01; H10N 50/10

(52) U.S. Cl. CPC H10B 61/10; H10N 50/01; H10N 50/10

(57) ABSTRACT

In an embodiment, a semiconductor device includes: a variable resistance pattern configured to switch between different resistance states in response to an applied voltage or current; and a selector pattern disposed over the variable resistance pattern and having a lower surface in direct contact with an upper surface of the variable resistance pattern, the selector pattern structured to include an insulating material doped with dopants and to exhibit a threshold switching behavior to exhibit, and selectively switch between, an (1) electrical conducting state of providing an electrical conducting path in the selector pattern, and (2) an electrical non-conducting state of turning off the electrical conducting path in the selector pattern, wherein a sidewall of the variable resistance pattern and a sidewall of the selector pattern are aligned with each other.

### CROSS-REFERENCE TO RELATED APPLICATION

This patent document claims the priority and benefits of Korean Patent Application No. 10-2023-0135130 filed on Oct. 11, 2023, which is incorporated herein by reference in its entirety.

### TECHNICAL FIELD

The technology disclosed in this patent document relates to a semiconductor technology, and more particularly, to a semiconductor device including a selector, and a method for fabricating the same.

### BACKGROUND

With the recent trend toward miniaturization, low power consumption, high performance, and multi-functionality in the electrical and electronics industry, the semiconductor manufacturers are focusing on high-performance, high capacity semiconductor devices. Examples of such high-performance, high-capacity semiconductor devices include semiconductor devices that can store data by switching between different resistance states based on an applied voltage or current, such as resistive random access memory (RRAM), phase change random access memory (PRAM), ferroelectric random access memory (FRAM), magnetic random access memory (MRAM), and electronic fuse (E-fuse).

### SUMMARY

In an embodiment, a semiconductor device may include: a variable resistance pattern configured to switch between different resistance states in response to an applied voltage or current; and a selector pattern disposed over the variable resistance pattern and having a lower surface in direct contact with an upper surface of the variable resistance pattern, the selector pattern structured to include an insulating material doped with dopants and to exhibit a threshold switching behavior to exhibit, and selectively switch between, an (1) electrical conducting state of providing an electrical conducting path in the selector pattern, and (2) an electrical non-conducting state of turning off the electrical conducting path in the selector pattern, wherein a sidewall of the variable resistance pattern and a sidewall of the selector pattern are aligned with each other.

In an embodiment, a method for fabricating a semiconductor device, may include: forming a variable resistance layer configured to switch between different resistance states in response to an applied voltage or current; forming an insulating pattern over the variable resistance layer; performing a first etching process to etch a portion of the variable resistance layer using the insulating pattern as an etch barrier; and performing a second etching process to etch a remaining portion of the variable resistance layer using the insulating pattern as an etch barrier to form a variable resistance pattern, wherein, during the second etching process, dopants are implanted into the insulating pattern by flowing a dopant-containing gas, and the insulating pattern into which the dopants are implanted forms a selector pattern.

### BRIEF DESCRIPTION OF THE DRAWINGS

FIG. 1 is a perspective view illustrating a semiconductor device based on an embodiment of the disclosed technology.

FIG. 2 is a cross-sectional view illustrating an example of the selector unit based on an embodiment of the disclosed technology.

FIG. 3 is a view illustrating an example operation of the selector unit of FIG. 2.

FIGS. 4A to 4C are cross-sectional views illustrating a semiconductor device and a method for fabricating the same, based on another embodiment of the disclosed technology.

FIG. 5 is an enlarged view of a portion of the semiconductor device of FIG. 4C.

FIG. 6 is a cross-sectional view illustrating a semiconductor device based on another embodiment of the disclosed technology.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

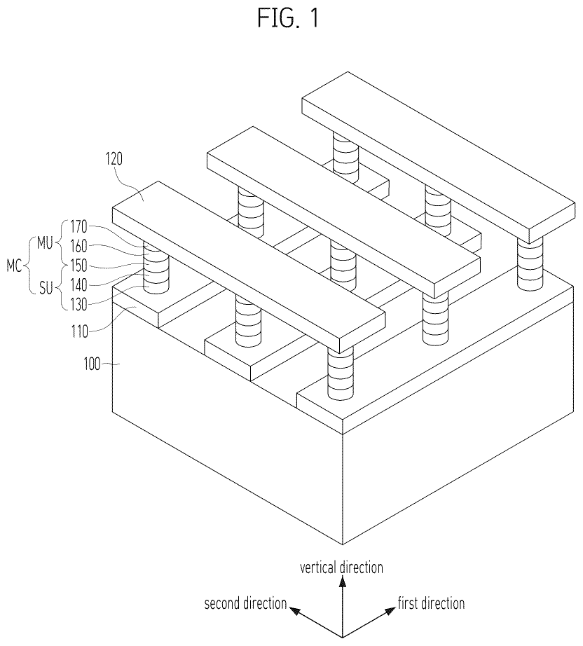

FIG. 1 is a perspective view illustrating a semiconductor device based on an embodiment of the disclosed technology.

Referring to FIG. 1, the semiconductor device based on an embodiment may include a substrate 100, a plurality of first conductive lines 110 disposed over the substrate 100 and extending in a first direction, a plurality of second conductive lines 120 disposed over the first conductive lines 110 and extending in a second direction intersecting the first direction, and a plurality of memory cells MC interposed between the first conductive lines 110 and the second conductive lines 120 and respectively overlapping intersection regions of the first conductive lines 110 and the second conductive lines 120. Here, the first direction and the second direction may be substantially parallel to the upper surface of the substrate 100. In some implementations, a direction substantially perpendicular to the upper surface of the substrate 100 may be referred to as a vertical direction.

The substrate 100 may include a semiconductor material such as silicon. In addition, the substrate 100 may include a desired lower structure (not shown). As an example, the substrate 100 may include an integrated circuit for driving (e.g., control, select, activate, etc.) the first conductive lines 110 and/or the second conductive lines 120.

The first conductive lines 110 may be arranged to be spaced apart from each other in the second direction. The first conductive line 110 may include at least one of various conductive materials, for example, a metal such as platinum (Pt), tungsten (W), aluminum (Al), copper (Cu), tantalum (Ta), or titanium (Ti), a metal nitride such as titanium nitride (TiN), tantalum nitride (TaN), or tungsten nitride (WN), or a combination thereof, and may have a single-layer structure or a multi-layer structure.

The second conductive lines 120 may be arranged to be spaced apart from each other in the first direction. The second conductive lines 120 may include at least one of various conductive materials, for example, a metal such as platinum (Pt), tungsten (W), aluminum (Al), copper (Cu), tantalum (Ta), or titanium (Ti), a metal nitride such as titanium nitride (TiN), tantalum nitride (TaN), or tungsten nitride (WN), or a combination thereof, and may have a single-layer structure or a multi-layer structure.

Each of the memory cells MC may include a memory unit MU, configured to store data, and a selector unit SU that controls access to the memory unit MU. As an example, the memory cell MC may include a stacked structure that includes a lower electrode layer 130, a selector layer 140, an intermediate electrode layer 150, a variable resistance layer 160, and an upper electrode layer 170. Here, the selector unit SU may include the lower electrode layer 130, the selector layer 140, and the intermediate electrode layer 150, and the memory unit MU may include the intermediate electrode layer 150, the variable resistance layer 160, and the upper electrode layer 170. The intermediate electrode layer 150 may be shared by the selector unit SU and the memory unit MU.

The lower electrode layer 130 and the upper electrode layer 170 may be positioned at the bottom and top of the memory cell MC, respectively, and may function as a passage through which a voltage or current is transmitted. The intermediate electrode layer 150 may function to electrically connect the selector layer 140 and the variable resistance layer 160 while physically separating them. The lower electrode layer 130, the intermediate electrode layer 150, or the upper electrode layer 170 may include at least one of various conductive materials, for example, a metal such as platinum (Pt), tungsten (W), aluminum (Al), copper (Cu), tantalum (Ta), or titanium (Ti), a metal nitride such as titanium nitride (TiN), tantalum nitride (TaN), or tungsten nitride (WN), or a combination thereof. In some implementations, the lower electrode layer 130, the intermediate electrode layer 150, or the upper electrode layer 170 may include a carbon electrode.

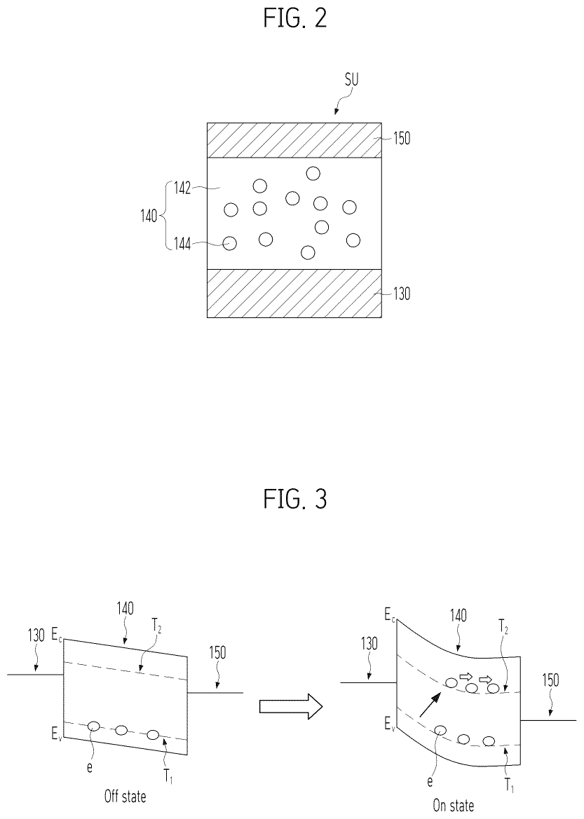

The selector layer 140 may control access to the variable resistance layer 160 while preventing or reducing current leakage that may occur between the memory cells MC sharing the first conductive line 110 or the second conductive line 120. To this end, the selector layer 140 may have a threshold switching characteristic in response to an applied voltage and can exhibit, and selectively switch between, an (1) electrical conducting state of providing an electrical conducting path in the selector layer 140, and (2) an electrical non-conducting state of turning off the electrical conducting path in the selector layer 140. For example, a current is blocked or hardly flows in the selector layer 140 to turn off the electrical conducting path when the magnitude of the voltage applied to the selector layer 140 is less than a predetermined threshold voltage, and the electrical conducting path is provided to allow the current to flow through the selector layer 140 and increase rapidly at a voltage equal to or higher than the threshold voltage. That is, the selector layer 140 may be turned on when the applied voltage is higher than the threshold voltage and may be turned off when the applied voltage is lower than the threshold voltage. In implementations, the selector layer 140 may include an insulating material implanted with a dopant. The selector unit SU including the selector layer 140 and its operation will be described in more detail with reference to FIGS. 2 and 3 below.

FIG. 2 is a cross-sectional view illustrating an example of the selector unit based on an embodiment of the disclosed technology.

Referring to FIG. 2, the selector unit SU may include the lower electrode layer 130, the selector layer 140, and the intermediate electrode layer 150.

As described above, the lower electrode layer 130 and the intermediate electrode layer 150 may include at least one of various conductive materials such as a metal and a metal nitride. The lower electrode layer 130 and the intermediate electrode layer 150 may be formed of the same material, and accordingly, may have the same work function. As an example, the lower electrode layer 130 and the intermediate electrode layer 150 may include titanium nitride (TiN) having a work function of 4.4 to 4.6 eV. However, the disclosed technology is not limited to this example, and the lower electrode layer 130 and the intermediate electrode layer 150 may be formed of different materials, and accordingly, may have different work functions.

The selector layer 140 may include an insulating material layer 142, and dopants 144 implanted into the insulating material layer 142.

The insulating material layer 142 may include an insulating material with a relatively wide band gap, for example, with a band gap of 5.0 eV or more. As an example, the insulating material layer 142 may include a silicon-containing insulating material such as silicon oxide, silicon nitride, or silicon oxynitride, an insulating metal oxide, an insulating metal nitride, or a combination thereof. There may be deep traps within the insulating material layer 142. The deep traps may have an energy level closer to the energy level of the valence band of the insulating material layer 142 than the energy level of the conduction band of the insulating material layer 142. The dopants 144 may serve to create shallow traps that provides a passage for conductive carriers (e.g., electrons or holes) to move within the insulating material layer 142. The shallow traps may have an energy level closer to the energy level of the conduction band of the insulating material layer 142 than the energy level of the valence band of the insulating material layer 142. As an example, when the insulating material layer 142 contains silicon, the dopants 144 may include a metal having a valence different from that of silicon, such as gallium (Ga), boron (B), indium (In), phosphorus (P), arsenic (As), antimony (Sb), germanium (Ge), carbon (C), tungsten (W), or a combination thereof. In some implementations, when the insulating material layer 142 contains a metal, the dopants 144 may include silicon or another metal having a valence different from that of the metal. As an example, the insulating material layer 142 may include silicon oxide, for example, silicon dioxide (SiO₂), and the dopants 144 may include arsenic (As). That is, the selector layer 140 may include silicon dioxide (SiO₂) doped with arsenic (As).

The operation of the selector unit SU will be described with reference to FIG. 3 as follows.

FIG. 3 is a view illustrating an example operation of the selector unit of FIG. 2.

Referring to FIG. 3, in an “off” state in which no voltage is applied to the selector unit SU, conductive carriers, for example, electrons (e), may be trapped in the deep traps T1 of the selector layer 140.

When a voltage higher than the threshold voltage is applied to the selector unit SU in the off state through the lower electrode layer 130 and the upper electrode layer 150, an “on” state in which a current flows through the selector unit SU may be implemented. In some implementations, when the voltage higher than the threshold voltage is applied to the selector unit SU, the conductive carriers trapped in the deep traps T1 may jump to the shallow traps T2 by thermal emission or tunneling, and the conductive carriers may move through the shallow traps T2 thereby forming a conductive path connecting the lower electrode layer 130 and the upper electrode layer 150.

When the voltage applied to the selector unit SU in the on state decreases, the number of conductive carriers moving from the deep traps T1 to the shallow traps T2 may decrease, and the selector unit SU may be turned off again.

In this way, the selector unit SU may be turned on or turned off.

Referring again to FIG. 1, the variable resistance layer 160 may be a part that stores data in the memory cell MC. To this end, the variable resistance layer 160 may have a variable resistance characteristic that switches between different resistance states based on a voltage or current applied thereto. The variable resistance layer 160 may have a single-layer structure or a multi-layer structure including at least one of various materials used in RRAM, PRAM, FRAM, MRAM, etc., for example, a metal oxide such as a transition metal oxide or a perovskite-based material, a phase change material such as a chalcogenide-based material, a ferroelectric material, and a ferromagnetic material. Furthermore, as an example, the variable resistance layer 160 may include a magnetic tunnel junction structure including a pinned layer, a tunnel barrier layer, and a free layer.

The memory cell MC may have a pillar shape that overlaps the intersection region of the first conductive line 110 and the second conductive line 120. In this figure, the memory cell MC is shown as having a cylindrical shape, but the disclosed technology is not limited to this, and the memory cell MC may have various shapes such as a square pillar, a rectangular pillar, an elliptical pillar, or the like.

In some implementations, the layer structure of the memory cell MC is not limited to what is shown in the drawings. The stacking order of the layers of memory cell MC may be changed, one or more of the layers of the memory cell MC may be omitted, or one or more additional layers may be added to the memory cell MC. As an example, one or more of the lower electrode layer 130, intermediate electrode layer 150, and upper electrode layer 170 may be omitted. Alternatively, the positions of the selector layer 140 and the variable resistance layer 160 may be reversed with each other. In some implementations, one or more layers (not shown) may be added to the memory cell MC to improve the process or the characteristics of the memory cell MC.

In an embodiment, when the variable resistance layer 160 has a multi-layer structure such as a magnetic tunnel junction structure, it may be difficult to collectively etch the layers 130 to 170 forming the memory cell MC using a single mask. In this case, the selector layer 140 and the variable resistance layer 160 may be patterned separately using different masks, so they may have sidewalls that are not aligned with each other. When patterning the selector layer 140 and the variable resistance layer 160 using different masks, the fabrication processes may become complicated, and the production cost may increase. In addition, when the selector layer 140 and the variable resistance layer 160 are etched together using a single mask, process difficulty may increase due to an increase in the thickness of the etching target, and the characteristics of the selector layer 140 and/or the variable resistance layer 160 may be deteriorated due to the abnormal etching.

The disclosed technology can be implemented in some embodiments to provide a semiconductor device that includes an insulating material layer as a selector and a method for fabricating the semiconductor device, as will be described below.

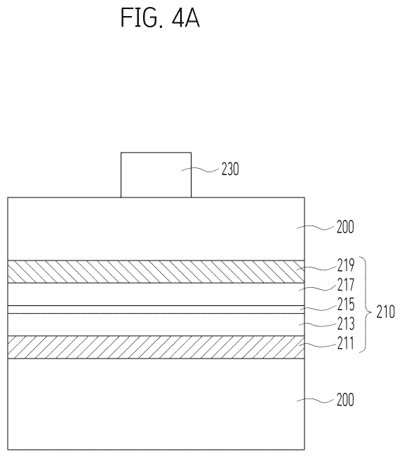

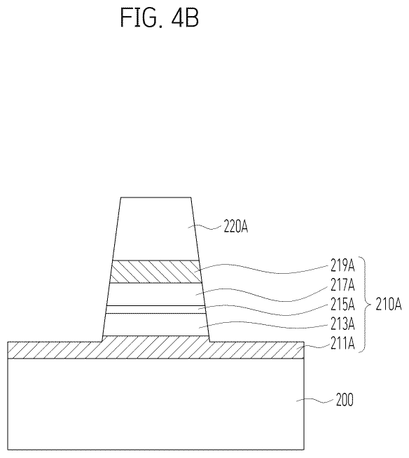

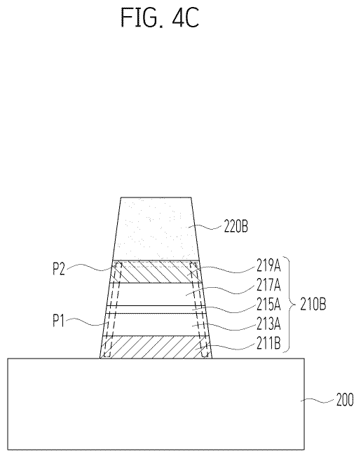

FIGS. 4A to 4C are cross-sectional views illustrating a semiconductor device and a method for fabricating the same, based on another embodiment of the disclosed technology.

In an embodiment, the fabricating method may include the following operations.

Referring to FIG. 4A, the fabricating method may include forming a substrate 200 that includes a predetermined lower structure. The substrate 200 may include various electric circuits. For example, the substrate 200 may include a conductive line similar to the first conductive line 110 of FIG. 1 described above.

Subsequently, a variable resistance layer 210 may be formed over the substrate 200. The variable resistance layer 210 may have a multi-layer structure in which two or more layers are stacked. As an example, the variable resistance layer 210 may include a magnetic tunnel junction structure in which a lower conductive layer 211, a pinned layer 213, a tunnel barrier layer 215, a free layer 217, and an upper conductive layer 219 are stacked.

The pinned layer 213 may be a layer that has a fixed magnetization direction and may be used as a reference layer that is compared to the magnetization direction of the free layer 217. The free layer 217 may be used as a storage layer that can store different data bits by changing a magnetization direction. The tunnel barrier layer 215 may physically separate the pinned layer 213 from the free layer 217, and may enable tunneling of electrons between them. Each of the pinned layer 213 and the free layer 217 may have a single-layer or multi-layer structure including a ferromagnetic material. As an example, each of the pinned layer 213 and the free layer 217 may include an alloy including Fe, Ni, or Co as a main component, such as Fe—Pt alloy, Fe—Pd alloy, Co—Pd alloy, Co—Pt alloy, Fe—Ni—Pt alloy, Co—Fe—Pt alloy, Co—Ni—Pt alloy, Fe—Pd alloy, and Co—Fe—B alloy, or a stacked structure of Co/Pt or Co/Pd. In one example, the tunnel barrier layer 215 may have a single-layer structure that includes an insulating material. In another example, the tunnel barrier layer 215 may have a multi-layer structure that includes an insulating material. As an example, the tunnel barrier layer 215 may include an insulating oxide such as MgO, CaO, SrO, TiO, VO, or NbO. In one example, as shown in FIGS. 4A-4C, the free layer 217 may be located above the tunnel barrier layer 215, and the pinned layer 213 may be located below the tunnel barrier layer 215. In another example, the pinned layer 213 may be located above the tunnel barrier layer 215, and the free layer 217 may be located below the tunnel barrier layer 215.

The lower conductive layer 211 may be located at the bottom of the variable resistance layer 210 to enable electrical connection between the substrate 200 and the variable resistance layer 210, and may perform various functions to improve the characteristics of the variable resistance layer 210. For example, the lower conductive layer 211 may function as a seed layer that helps crystal growth of a magnetic layer located over the lower conductive layer 211, for example, the pinned layer 213. The lower conductive layer 211 may include a non-magnetic conductive material. As an example, the lower conductive layer 211 may include a metal such as tungsten (W), ruthenium (Ru), titanium (Ti), tantalum (Ta), molybdenum (Mo), nickel (Ni), or chromium (Cr), a metal nitride such as titanium nitride (TiN), tantalum nitride (TaN), or tungsten nitride (WN), or a combination thereof. The lower conductive layer 211 may be omitted.

The upper conductive layer 219 may be located at the top of the variable resistance layer 210 to enable electrical connection between the variable resistance layer 210 and a selector pattern (see 220B in FIG. 4C) to be described later, and may perform various functions to improve the characteristics of the variable resistance layer 210. For example, the upper conductive layer 219 may function as a capping layer that protects a magnetic layer located below the upper conductive layer 219, such as the free layer 219. In addition, the upper conductive layer 219 may function to prevent dopants from diffusing into a magnetic material, such as the free layer 217, as will be described below. The upper conductive layer 219 may include a non-magnetic conductive material. As an example, the upper conductive layer 219 may include a metal such as tungsten (W), ruthenium (Ru), titanium (Ti), tantalum (Ta), molybdenum (Mo), nickel (Ni), or chromium (Cr), a metal nitride such as titanium nitride (TiN), tantalum nitride (TaN), or tungsten nitride (WN), or a combination thereof.

Subsequently, an insulating material layer 220 may be formed over the variable resistance layer 210. The insulating material layer 220 may be used to form a selector, and may be formed by depositing an insulating material. As an example, the insulating material layer 220 may include a silicon-containing insulating material such as silicon oxide, silicon nitride, or silicon oxynitride, an insulating metal oxide, an insulating metal nitride, or a combination thereof. In an example, the insulating material layer 220 may include silicon dioxide.

Subsequently, a mask pattern 230 is used to form a pillar shape over the insulating material layer 220 by patterning the variable resistance layer 210 and the insulating material layer 220. The mask pattern 230 may include at least one of various materials such as metal, and may have a single-layer structure or a multi-layer structure.

Referring to FIG. 4B, the insulating material layer 220 may be etched using the mask pattern 230 as an etch barrier to form an insulating pattern 220A.

The disclosed technology can be implemented in some embodiments to address the issues discussed over by etching the variable resistance layer 210 using the insulating pattern 220A as an etch barrier. In one example, a portion of the variable resistance layer 210 may be etched to form an initial variable resistance pattern 210A. When the portion of the variable resistance layer 210 is etched, a remaining portion of the variable resistance layer 210 may remain without being etched. The partial etching process of the variable resistance layer 210 for forming the initial variable resistance pattern 210A will hereinafter be referred to as a first etching process. The first etching process may be performed using an ion beam etching (IBE) process. While the formation process of the insulating pattern 220A and/or the first etching process are being performed, the mask pattern 230 may be removed. The disclosed technology can be implemented in some embodiments to use the insulating pattern 220A as a hard mask for partial etching of the variable resistance layer 210 even after the mask pattern 230 is removed.

In an embodiment, during the first etching process, the upper conductive layer 219, the free layer 217, the tunnel barrier layer 215, the pinned layer 213, and a portion of the lower conductive layer 211 may be etched. The etched upper conductive layer 219, the etched free layer 217, the etched tunnel barrier layer 215, the etched pinned layer 213, and the etched lower conductive layer 211 will be referred to as an upper conductive pattern 219A, a free pattern 217A, a tunnel barrier pattern 215A, a pinned pattern 213A, and an initial lower conductive pattern 211A, respectively. The initial variable resistance pattern 210A may include the upper conductive pattern 219A, the free pattern 217A, the tunnel barrier pattern 215A, the pinned pattern 213A, and the initial lower conductive pattern 211A. However, the disclosed technology is not limited to this example, and the etch depth during the first etching process may vary. That is, during the first etching process, the first thickness T1 of the etched portion of the variable resistance layer 210 and the second thickness T2 of the remaining portion of the variable resistance layer 210 may vary. In one example, the first thickness T1 may be greater than the second thickness T2, because the first etching process is the main process of the etching processes of the variable resistance layer 210. The sum of the first thickness T1 and the second thickness T2 may correspond to the total thickness of the variable resistance layer 210 or the initial variable resistance pattern 210A.

Referring to FIG. 4C, the remaining portion of the initial variable resistance pattern 210A exposed by the insulating pattern 220A may be etched to form a variable resistance pattern 210B. The partial etching process of the initial variable resistance pattern 220B for forming the variable resistance pattern 210B will hereinafter be referred to as a second etching process. The second etching process may be performed using IBE. The second etching process may be performed in-situ with the first etching process in succession to the first etching process.

In some implementations, by flowing a dopant-containing gas during the second etching process, dopants may be doped/implanted into the insulating pattern 220A to form a selector pattern 220B. The dopants may include an element capable of creating shallow traps that provides a passage for conductive carriers (e.g., electrons or holes) within the insulating pattern 220A. The dopants may include an element with a different valence from the constituent elements of the insulating pattern 220m for example, gallium (Ga), boron (B), indium (In), phosphorus (P), arsenic (As), antimony (Sb), germanium (Ge), carbon (C), tungsten (W), or a combination thereof. When the insulating pattern 220A includes silicon dioxide, the dopants may include arsenic, and thus, the selector pattern 220B including silicon dioxide implanted with arsenic may be formed. In this case, the dopant-containing gas may be, for example, arsenic gas.

During the second etching process, the insulating pattern 220A and/or the selector pattern 220B may function as a hard mask for the second etching process. In an embodiment, during the second etching process, the remaining portion of the initial lower conductive pattern 211A, which was not etched in the first etching process, may be etched. The etched initial lower conductive pattern 211A, which is etched by the second etching process, may be referred to as a lower conductive pattern 211B, and the variable resistance pattern 210B may include the upper conductive pattern 219A, the free pattern 217A, the tunnel barrier pattern 215A, the pinned pattern 213A, and the lower conductive pattern 211B. The second etching process may be an additional etching process that is performed in addition to the first etching process. In other words, the first thickness T1 of the portion etched during the first etching process may be greater than the second thickness T2 of the portion etched during the second etching process. Accordingly, the time it takes to perform the second etching process may be shorter than the time it takes to perform the first etching process. Except for flowing more dopant-containing gas and shorter process time during the second etching process, the conditions of the second etching process may be substantially the same as the conditions of the first etching process.

In some implementations, the dopants by the second etching process may be implanted not only into the insulating pattern 220A but also into the variable resistance pattern 210B. Since the upper surface of the variable resistance pattern 210B is covered during the second etching process, the dopants may be implanted into a portion from the sidewall of the variable resistance pattern 210B at a predetermined width. The region into which the dopants are implanted from the sidewall of the variable resistance pattern 210B will hereinafter be referred to as a first dopant region P1. Because the second etching process is performed for a relatively short period of time, the size of the first dopant region P1 may not be large. Accordingly, even if the first dopant region P1 exists in the portion of the sidewall of the variable resistance pattern 210B, the characteristics of the variable resistance pattern 210B may not be significantly affected.

In addition, the dopants of the selector pattern 220B may diffuse through the upper surface of the variable resistance pattern 210B, so the dopants may be implanted into a portion from the upper surface of the variable resistance pattern 210B at a predetermined depth. The region into which the dopants are implanted from the upper surface of the variable resistance pattern 210B will hereinafter be referred to as a second dopant region P2. Since the second etching process is performed for a relatively short period of time, the degree of diffusion of the dopants may not be relatively large, so the size of the second dopant region P2 may not be large. Accordingly, even if the second dopant region P2 exists in the portion of the upper surface of the variable resistance pattern 210B, it may not significantly affect the characteristics of the variable resistance pattern 210B. In particular, the second dopant region P2 may be formed in a portion from the upper surface of the upper conductive pattern 219A at a predetermined depth. That is, the second dopant region P2 may be disposed in the upper conductive pattern 219A that is disposed at the uppermost portion of the variable resistance pattern 210B. Since the upper conductive pattern 219A functions as a diffusion barrier for the dopants, the second dopant region P2 may not be formed in a magnetic material, such as the free layer 217A, which directly affects the variable resistance characteristic of the variable resistance pattern 210B, and thus, it may be possible to prevent deterioration of the characteristics of the variable resistance pattern 210B caused by the dopants.

The semiconductor device based on an embodiment may be fabricated through the processes described above.

Referring again to FIG. 4C, the semiconductor device based on an embodiment may include the substrate 200, the variable resistance pattern 210B formed over the substrate 200, and the selector pattern 220B formed over the variable resistance pattern 210B. The selector pattern 220B may include an insulating material implanted with dopants.

Here, since the variable resistance pattern 210B is formed through an etching process using the selector pattern 220B and/or the insulating pattern 220A as a hard mask, the sidewall of the variable resistance pattern 210B may be aligned with the sidewall of the selector pattern 220B. In addition, the upper surface of the variable resistance pattern 210B, for example, the upper surface of the upper conductive pattern 219A, may directly contact the lower surface of the selector pattern 220B. In other words, an electrode layer between the variable resistance pattern 210B and the selector pattern 220B, for example, the intermediate electrode layer (see 150 in FIG. 1) may be omitted.

The first dopant region P1 may be formed in the portion from the sidewall of the variable resistance pattern 210B. The second dopant region P2 may be formed in the portion from the upper surface of the variable resistance pattern 210B, for example, from the upper surface of the upper conductive pattern 219A. The first dopant region P1 and the second dopant region P2 may include the dopants implanted into the selector pattern 220B.

Based on the semiconductor device and its fabricating method, since the selector pattern 220B and the insulating pattern 220A are used as hard masks for the first and second etching processes, the processes may be simplified, and the process cost may be reduced. In addition, it may be advantageous to secure the characteristics of the selector pattern 220B and the variable resistance pattern 210B by reducing the process difficulty.

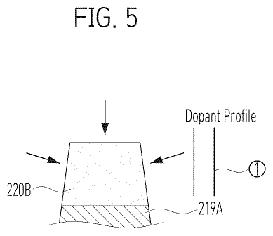

Furthermore, since the dopants are implanted through the sidewall and the upper surface of the insulating pattern 220A, there may be an advantage in that the dopant profile is improved. This will be described in more detail with reference to FIG. 5.

FIG. 5 is an enlarged view of a portion of the semiconductor device of FIG. 4C.

Referring to FIG. 5, in the dopant profile indicated at the right side of the selector pattern 220B, it can be seen that the dopant concentration based on depth in the vertical direction is substantially constant (see \textcircled{1}).

This may be because, in the second etching process, the dopant-containinggas, such as arsenic gas, flows in a state in which the sidewall and the upper surface of the insulating pattern 220A are exposed, and thus, the dopants are implanted in a direction toward the sidewall and the upper surface of the insulating pattern 220A. In other words, the dopants may be implanted in the direction indicated by the arrow to form the selector pattern 220B.

If a selector is formed by implanting dopants using an ion implantation method toward an upper surface of an insulating material layer as in the prior art, the dopant concentration depending on the depth in the vertical direction may not constant and may vary greatly. This may be because, during the ion implantation process, Gaussian distribution appears in which the dopant concentration is maximum at a specific depth of the selector and rapidly decreases as the distance from the specific depth increases in the vertical direction.

As a result, in an embodiment, since the dopant concentration in the selector pattern 220B is substantially constant depending on the depth, the switching characteristics of the selector pattern 220B may be improved.

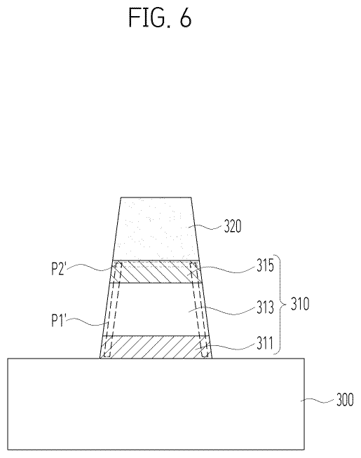

Meanwhile, in the above embodiment, a case where the variable resistance pattern includes a magnetic tunnel junction structure has been described, but the disclosed technology is not limited to this. As long as the variable resistance pattern can store different data by switching between different resistance states depending on the voltage or current applied thereto, the variable resistance pattern may include various materials, and may have various layer structures. This will be illustratively described with reference to FIG. 6.

FIG. 6 is a cross-sectional view illustrating a semiconductor device based on another embodiment of the disclosed technology.

Referring to FIG. 6, the semiconductor device based on an embodiment may include a substrate 300, a variable resistance pattern 310 formed over the substrate 300, and a selector pattern 320 formed over the variable resistance pattern 310. The selector pattern 320 may include an insulating material implanted with dopants.

Here, the variable resistance pattern 310 may include a lower conductive pattern 311, a variable resistance material layer 313, and an upper conductive pattern 315. As an example, the variable resistance material layer 313 may include a phase change material. In this case, the crystalline state of the phase change material may switch between an amorphous state and a crystalline state depending on the voltage or current applied to the variable resistance pattern 310, so the resistance state of the variable resistance pattern 310 may switch between a high resistance state and a low resistance state. Alternatively, as an example, the variable resistance material layer 313 may include a metal oxide. In this case, a conductive path due to metal ions or oxygen vacancies may be created or destroyed depending on the voltage or current applied to the variable resistance pattern 310, so the resistance state of the variable resistance pattern 310 may switch between a high resistance state and a low resistance state.

A first dopant region P1′ may be formed in a portion from the sidewall of the variable resistance pattern 310. A second dopant region P2′ may be formed in a portion from the upper surface of the variable resistance pattern 130, for example, from the upper surface of the upper conductive pattern 315. The first dopant region P1′ and the second dopant region P2′ may include the dopants implanted into the selector pattern 320.

Based on the semiconductor device and its fabricating method of the above embodiments of the disclosed technology, the fabricating process may be facilitated, and the characteristics may be improved.

Although various embodiments have been described for illustrative purposes, it will be apparent to those skilled in the art that various changes and modifications may be made without departing from the spirit and scope of the present teachings as defined in the following claims.

What is claimed is:

1. A semiconductor device comprising:
a variable resistance pattern configured to switch between different resistance states in response to an applied voltage or current; and
a selector pattern disposed over the variable resistance pattern and having a lower surface in direct contact with an upper surface of the variable resistance pattern, the selector pattern structured to include an insulating material doped with dopants and to exhibit a threshold switching behavior to exhibit, and selectively switch between, an (1) electrical conducting state of providing an electrical conducting path in the selector pattern, and (2) an electrical non-conducting state of turning off the electrical conducting path in the selector pattern,
wherein a sidewall of the variable resistance pattern and a sidewall of the selector pattern are aligned with each other.

2. The semiconductor device according to claim 1, wherein the variable resistance pattern includes a portion including the dopants and extending from the sidewall of the variable resistance pattern toward an inside of the variable resistance pattern.

3. The semiconductor device according to claim 1, wherein the variable resistance pattern includes a portion including the dopants and extending from the upper surface of the variable resistance pattern in direct contact with the selector pattern toward an inside of the variable resistance pattern.

4. The semiconductor device according to claim 1, wherein the variable resistance pattern includes:
a conductive pattern disposed at an uppermost portion of the variable resistance pattern, and
a portion including the dopants and extending from an upper surface of the conductive pattern toward an inside of the variable resistance pattern.

5. The semiconductor device according to claim 4, wherein the variable resistance pattern includes a magnetic tunnel junction structure that is disposed under the conductive pattern and includes a pinned layer with a fixed magnetization direction, a free layer with a changeable magnetization direction, and a tunnel barrier layer between the pinned layer and the free layer.

6. A method for fabricating a semiconductor device, comprising:
forming a variable resistance layer configured to switch between different resistance states in response to an applied voltage or current;
forming an insulating pattern over the variable resistance layer;
performing a first etching process to etch a portion of the variable resistance layer using the insulating pattern as an etch barrier; and
performing a second etching process to etch a remaining portion of the variable resistance layer using the insulating pattern as an etch barrier to form a variable resistance pattern,
wherein, during the second etching process, dopants are implanted into the insulating pattern by flowing a dopant-containing gas, and
the insulating pattern into which the dopants are implanted forms a selector pattern.

7. The method according to claim 6, wherein a thickness of the portion of the variable resistance layer is greater than a thickness of the remaining portion of the variable resistance layer.

8. The method according to claim 6, wherein a time it takes to perform the first etching process is greater than a time it takes to perform the second etching process.

9. The method according to claim 6, wherein the dopants are implanted through an upper surface and a sidewall of the insulating pattern.

10. The method according to claim 6, wherein the first etching process and the second etching process are performed by an ion beam etching (IBE) method.

11. The method according to claim 6, wherein the first etching process and the second etching process are performed in-situ.

12. The method according to claim 6, wherein the dopants are implanted into a portion of the variable resistance pattern from a sidewall of the variable resistance pattern.

13. The method according to claim 6, wherein the dopants are implanted into a portion of the variable resistance pattern from an upper surface of the variable resistance pattern.

14. The method according to claim 13, wherein the variable resistance layer includes a conductive layer disposed at an uppermost portion of the variable resistance layer, and
the dopants are implanted into a portion of the conductive layer.

15. The method according to claim 14, wherein the variable resistance pattern includes a magnetic tunnel junction structure that is disposed under the conductive layer and includes a pinned layer with a fixed magnetization direction, a free layer with a changeable magnetization direction, and a tunnel barrier layer between the pinned layer and the free layer.

16. The method according to claim 6, wherein an upper surface of the variable resistance pattern is in direct contact with a lower surface of the selector pattern.

17. The method according to claim 6, wherein a sidewall of the variable resistance pattern is aligned with a sidewall of the selector pattern.
